(19) United States
(12) Patent Application Publication
(10) Pub. No.: US 2024/0385534 A1
(43) Pub. Date: Nov. 21, 2024

(54) MEASURING METHOD, LITHOGRAPHY METHOD, ARTICLE MANUFACTURING METHOD, STORAGE MEDIUM, AND LITHOGRAPHY APPARATUS

(71) Applicant: CANON KABUSHIKI KAISHA, Tokyo (JP)

(72) Inventors: SHINGO HANYUDA, Tochigi (JP); MASAKATSU YANAGISAWA, Tochigi (JP)

(21) Appl. No.: 18/662,101

(22) Filed: May 13, 2024

(30) Foreign Application Priority Data
May 16, 2023 (JP) 2023-080920

(51) Int. Cl. G03F 7/00

(52) U.S. Cl. CPC G03F 7/706839; G03F 7/70508; G03F 7/70608; G03F 7/70683; G03F 7/7085

(57) ABSTRACT

A measuring method is provided. The method includes detecting a plurality of marks including at least three marks existing on a substrate using a scope configured to capture images of the marks, calculating an evaluation value indicating a distribution state of positions of the plurality of detected marks, determining a type of a model formula representing a deformation component in a predetermined region of the substrate based on the calculated evaluation value, and specifying a shape of the predetermined region using the model formula of the determined type.

### BACKGROUND OF THE INVENTION

### Field of the Invention

The present invention relates to a measuring method, a lithography method, an article manufacturing method, a storage medium, and a lithography apparatus.

### Description of the Related Art

Due to recent high integration and miniaturization of semiconductor integrated circuits, the line widths of patterns formed on substrates have become very small. Along with this, further miniaturization is required in a lithography step of forming a pattern on a substrate.

In a lithography apparatus such as an exposure apparatus, a pattern is formed in a predetermined region (pattern region) on a substrate. For this reason, to meet the requirement of pattern miniaturization, it is important to accurately align the position of the substrate.

Conventionally, a method is executed in which before pattern formation, the position of an alignment mark (to be simply referred to as a “mark” hereinafter) formed near a pattern region on a substrate is measured, and the array of pattern regions is obtained, thereby performing alignment.

However, if a measurement error is caused by a plurality of factors such as substrate distortion during a processing step and measurement deception caused by the film thickness of an applied resist, alignment of each pattern region in a substrate cannot appropriately be performed by one method. To solve this problem, there is proposed a technique of selecting an alignment method in accordance with a feature of measurement position data for each pattern region. In Japanese Patent Laid-Open No. 07-037770, a method is described in which reliability of each measurement position data is determined based on fuzzy inference from the detection states of marks or the state of measurement data, and an alignment method is selected based on the variance and distribution of the reliability of the measurement position data.

However, due to a factor that, for example, a mark is not normally formed in the process of a preceding step, all marks existing on the substrate are not necessarily reliably detected using a scope. In addition, if a shot region of a pattern formation target is a peripheral shot region located on the outer periphery of the substrate, restrictions of mark arrangement are strict. In these cases, the positions of marks obtained by measurement may not be appropriately be distributed in a substrate or in one shot region and may be distributed one-sidedly in a certain region or direction. In this case, a correction value may not correctly be calculated, resulting in lowering of alignment accuracy.

### SUMMARY OF THE INVENTION

The present invention provides a technique advantageous in performing alignment at high accuracy.

The present invention in its one aspect provides a measuring method including detecting a plurality of marks including at least three marks existing on a substrate using a scope configured to capture images of the marks, calculating an evaluation value indicating a distribution state of positions of the plurality of detected marks, determining a type of a model formula representing a deformation component in a predetermined region of the substrate based on the calculated evaluation value, and specifying a shape of the predetermined region using the model formula of the determined type.

Further features of the present invention will become apparent from the following description of exemplary embodiments (with reference to the attached drawings).

### BRIEF DESCRIPTION OF THE DRAWINGS

FIG. 1 is a view showing the configuration of an exposure apparatus;

FIG. 2 is a view showing the configuration of a scope;

FIG. 3 is a view exemplarily showing a prealignment mark;

FIG. 4 is a view exemplarily showing a fine alignment mark;

FIGS. 5A and 5B are flowcharts of exposure processing;

FIGS. 6A and 6B are views exemplarily showing sample shot regions;

FIGS. 7A and 7B are views showing an example of a plurality of marks arranged in one shot region;

FIG. 8 is a flowchart of a measuring method;

FIG. 9 is a flowchart of a measuring method; and

FIG. 10 is a view showing the configuration of an information processing system.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### <First Embodiment>

The present disclosure is related to a lithography apparatus and method for transferring or forming a pattern or a film on a substrate, which are used in a manufacturing step of a device such as a semiconductor element. Examples of the lithography apparatus are an imprint apparatus, a film forming apparatus (planarization apparatus), and an exposure apparatus. The imprint apparatus is an apparatus that cures an imprint material supplied onto a substrate in a state in which a mold (original) is in contact with the imprint material, thereby forming a pattern on the substrate. The film forming apparatus is an apparatus that cures a curable composition supplied onto a substrate in a state in which a flat template is in contact with the curable composition, thereby forming a flat film on the substrate. The exposure apparatus is an apparatus that transfers a pattern of an original to a substrate via a projection optical system. For example, the exposure apparatus exposes a photoresist applied onto a substrate via an original (reticle) that is an exposure mask, thereby forming, on the photoresist, a latent image corresponding to the pattern of the original. Hereinafter, to provide a detailed example, an example in which the lithography apparatus is configured as an exposure apparatus will be explained.

FIG. 1 is a view showing the configuration of an exposure apparatus 1 according to this embodiment. The exposure apparatus 1 is an example of a lithography apparatus used in a manufacturing step of a device such as a semiconductor element. In this embodiment, the exposure apparatus 1 projects the pattern of an original 2 (a reticle or a mask) to a substrate 4 via a projection optical system 3, and exposes the substrate 4.

In FIG. 1, the exposure apparatus 1 projects the pattern of the original 2 to the substrate 4 via the projection optical system 3, and exposes the substrate 4. The exposure apparatus 1 includes the projection optical system 3 that projects (for example, reduction-projects) a pattern formed on the original 2, and a chuck 5 that holds the substrate 4 with an underlying pattern or a mark formed in the preceding step. Also, the exposure apparatus 1 can include a substrate stage 6 that holds the chuck 5 and positions the substrate 4 at a predetermined position, a scope 7 (alignment scope) that measures the position of a mark provided near the substrate 4, a controller CN (processor), a storage unit SU, and a display unit D. The substrate stage 6 can include a substrate driving mechanism that performs positioning of the substrate 4. The substrate driving mechanism performs positioning of the substrate 4 by driving the chuck 5. The scope 7 includes a microscope and an imaging element, and captures an image of a mark provided on the substrate 4. The controller CN can detect the position of the mark on the substrate 4 based on an image captured by the scope 7.

The controller CN is formed by, for example, a computer (information processing apparatus) including a CPU and a memory, and comprehensively controls the units of the exposure apparatus 1 in accordance with a program stored in the storage unit SU or the like. In this embodiment, the controller CN not only controls exposure processing for exposing the substrate 4 via the original 2, but also can function as a processor that obtains the array (a shot array or an array of regions) of a plurality of shot regions (predetermined regions) on the substrate. On the display unit D, a user interface screen (UI screen) showing settings and states of exposure processing is displayed. The controller CN can also function as a display controller that controls display of the UI screen. The storage unit SU stores a program of a measuring method of detecting, using the scope 7, a mark existing on the substrate 4 and specifying the shape of a predetermined region based on the detection result. In addition, the storage unit SU also stores a program configured to execute exposure processing for exposing the substrate 4 by controlling the units of the exposure apparatus 1, and various kinds of information (data). Note that the controller CN, the storage unit SU, and the display unit D may be formed as devices outside the exposure apparatus 1. For example, an information processing apparatus including the controller CN, the storage unit SU, and the display unit D may be configured as a server apparatus that manages the exposure apparatus 1. Alternatively, an information processing apparatus including the controller CN, the storage unit SU, and the display unit D may be configured as a simulation apparatus that performs simulation for determining a sample shot region. An input device (a mouse, a keyboard, or the like) (not shown) to be operated by a user is also connected to the controller CN. Note that the storage unit SU may be a semiconductor memory, a disk such as a hard disk, or a memory in another form. The program of the measuring method according to the embodiment may be stored in a computer-readable memory medium or may be provided to an information processing apparatus via a communication facility such as an electric communication line.

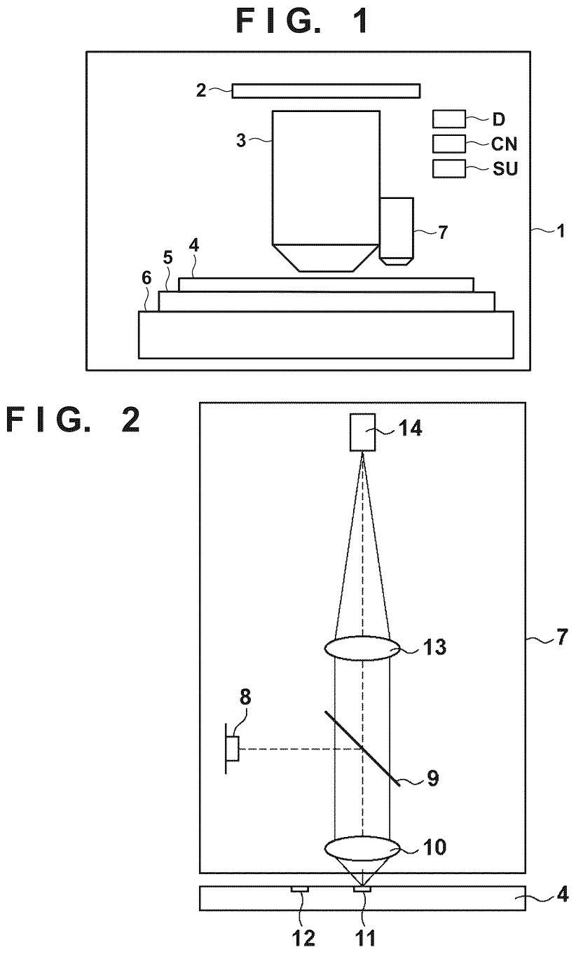

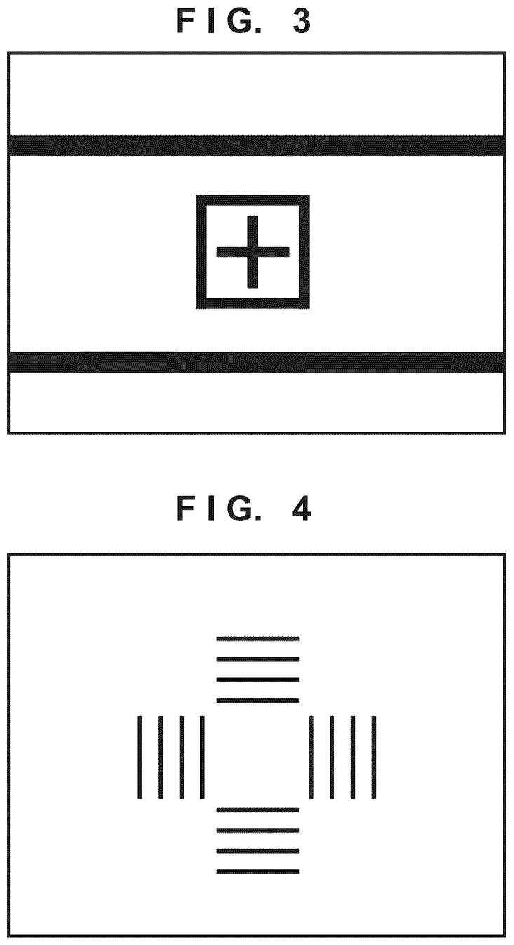

FIG. 2 shows an example of the configuration of the scope 7. The scope 7 can include, for example, a light source 8, a beam splitter 9, optical systems 10 and 13, and an imaging element 14. Illumination light emitted from the light source 8 is reflected by the beam splitter 9 and passed through the optical system 10 to illuminate a mark 11 or 12 on the substrate 4. Diffracted light from the mark 11 or 12 passes through the optical system 10, the beam splitter 9, and the optical system 13, and enters the imaging element 14, thereby forming an optical image of the mark 11 or 12 on the imaging surface of the imaging element 14. The imaging element 14 captures the optical image and outputs an image (image data) including a mark image (mark image data) that is the image (image data) of the mark 11 or 12. The light source 8, the beam splitter 9, and the optical systems 10 and 13 form a microscope configured to observe the mark 11 or 12. The microscope can have magnifications capable of implementing both prealignment measurement capable of searching for a mark in a wide range and fine alignment measurement capable of accurate measurement. Conventionally, since different optical systems are used for prealignment measurement and fine alignment measurement in many configurations, an alignment mark also uses a different shape depending on the application purpose. FIG. 3 shows the mark 11 for prealignment, and FIG. 4 shows the mark 12 for fine alignment. As for the shapes of the marks 11 and 12, optimum shapes according to the process of a wafer are often used, and various shapes exist.

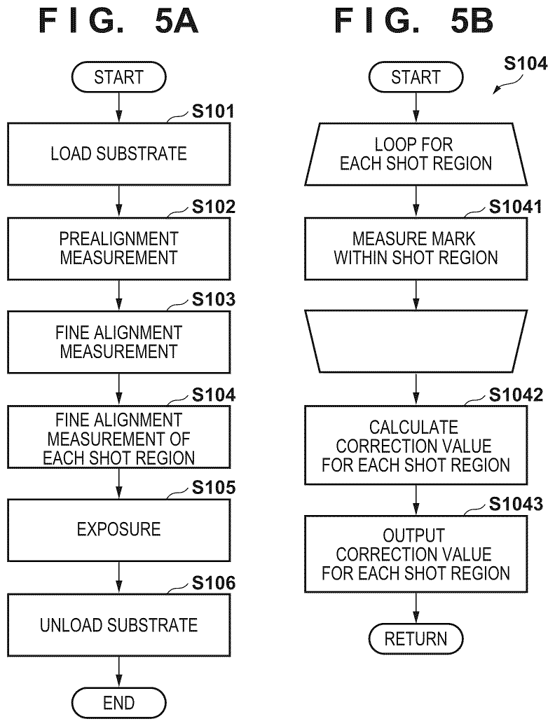

FIG. 5A shows the procedure of processing of exposing a substrate while performing alignment measurement. This processing is controlled by the controller CN. In step S101, the substrate 4 is loaded into the exposure apparatus 1 and held by the chuck 5. In step S102, prealignment measurement is performed. More specifically, in prealignment measurement, the position of the mark 11 for prealignment is detected using the scope 7, and the position of the substrate 4 is roughly calculated based on the result.

Next, in step S103, fine alignment is performed based on the result of prealignment measurement. In fine alignment, the substrate 4 is driven by the substrate driving mechanism of the substrate stage 6 based on the result of prealignment measurement such that the mark 12 for fine alignment is fitted at the center of the visual field of the scope 7 (drive-in). Here, prealignment (step S102) and fine alignment (step S103) are performed for a plurality of sample shot regions of the substrate 4, and accordingly, the whole substrate 4 can be shifted, and a 1st-order linear component (magnification and rotation) can be calculated. A higher-order deformation component of the substrate 4 may accurately be calculated by increasing the number of marks 12.

In step S104, fine alignment measurement is performed for a plurality of shot regions of the substrate 4. FIG. 5B shows a detailed procedure of step S104.

In step S1041, the mark 12 in a shot region of interest is measured on a shot region basis. In step S1042, a correction value is calculated for each shot region, and in step S1043, the correction value for each shot region is output. The correction value will be described later.

Next, in step S105, based on the result of fine alignment measurement, each shot region of the substrate 4 and the original 2 are aligned, and each shot region is exposed. After that, in step S106, the substrate 4 is unloaded.

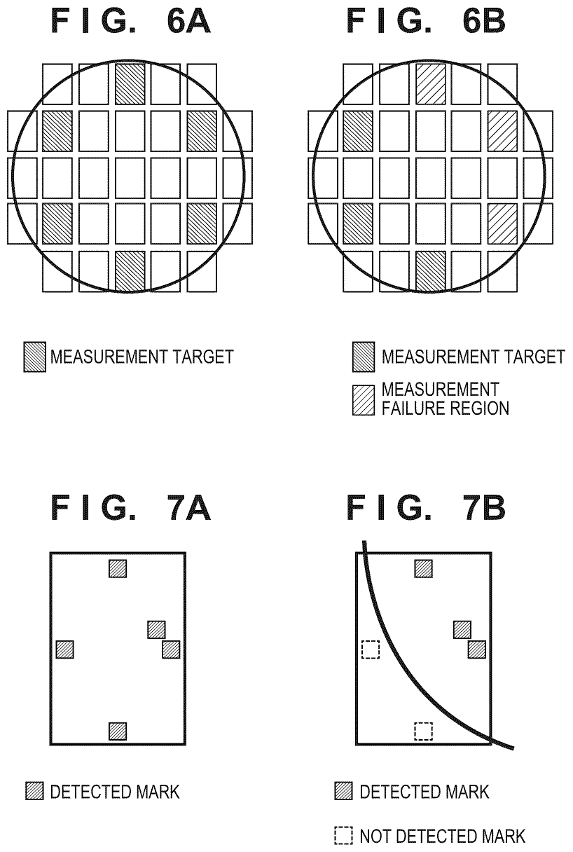

An example of the plurality of sample shot regions that are the targets of fine alignment measurement in step S103 will be described with reference to FIGS. 6A and 6B. FIG. 6A shows that alignment mark measurement is performed for six sample shot regions in the substrate. FIG. 6B shows an example in a case where measurement using the scope 7 has succeeded only for some regions of the six sample shot regions shown in FIG. 6A due to the influence of a substrate defect or the like. In the case shown in FIG. 6B, three sample shot regions for which the measurement using the scope 7 has succeeded are one-sidedly located on the left side of the substrate and linearly distributed. Hence, in this case, the marks 12 of the three sample shot regions for which the measurement using the scope 7 has succeeded are linearly distributed in the substrate. In such a case, in a direction orthogonal to the arrangement direction of the three sample shot regions, a correction value for the shift to the substrate shape or the 1st-order linear component (magnification/rotation) is not correctly calculated, and the alignment accuracy may lower.

Next, focus will be placed on one shot region that is the target of fine alignment measurement in step S104 with reference to FIGS. 7A and 7B. The number of marks arranged in one shot region is not limited to 1, and a plurality of marks can be arranged. FIG. 7A shows an example in which five marks are arranged in one shot region. FIG. 7A shows an example of a shot region located at a position at which the pattern of the original 2 is wholly fitted in the region of the substrate. Five marks are arranged in this shot region, and all the marks can be measured using the scope 7. On the other hand, FIG. 7B shows an example of a partial shot region which partially protrudes from the outer periphery of the substrate and to which only a part of the pattern of the original 2 is transferred. Here, relative to the partial shot region as shown in FIG. 7B, a shot region as shown in FIG. 7A is called a full shot region. In the example of the partial shot region shown in FIG. 7B, no marks exist in a portion corresponding to two marks arranged in the full shot region shown in FIG. 7A. In this case, as shown in FIG. 7B, only three marks are arranged in the partial shot region. Focusing the positions of the three marks arranged in the partial shot region, these are linearly distributed. Therefore, in a direction perpendicular to a direction in which the three marks are lined up, a correction value may not be calculated correctly, and the alignment accuracy may deteriorate.

Thus, in both a case where focus is placed on the entire substrate and a case where focus is placed on each shot region, alignment in which lowering of the alignment accuracy is suppressed needs to be performed in accordance with the distribution state of marks that are successfully detected using the scope 7.

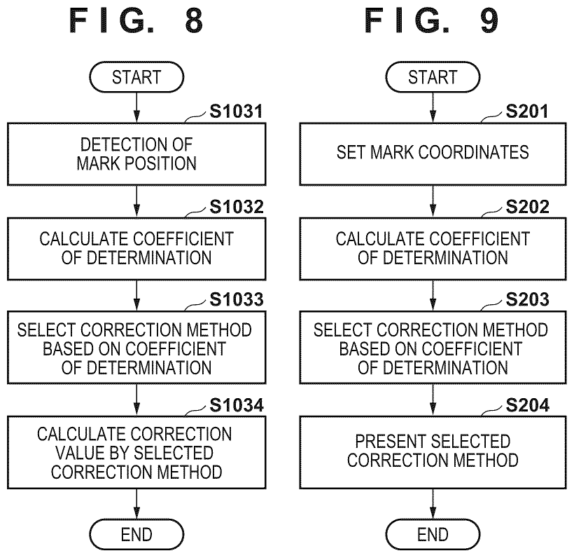

Processing (measuring method) performed in step S103 in which fine alignment measurement for aligning an exposure region to the substrate is executed will be described with reference to the flowchart of FIG. 8. This processing is controlled by the controller CN.

In step S1031, a plurality of marks including at least three marks existing on the substrate are detected using the scope 7 (first step). In the measuring method to be described here, the shape of a predetermined region of the substrate is measured. In an example, the predetermined region is the whole region of the substrate as shown in FIGS. 6A and 6B, and the plurality of marks are located in a plurality of sample shot regions of the substrate, respectively. In another example, the predetermined region is one shot region of the substrate as shown in FIGS. 7A and 7B, and the plurality of marks are located in one shot region.

In step S1032, the controller CN calculates an evaluation value indicating the distribution state of the positions of the plurality of detected marks (second step). In an example, the evaluation value is a coefficient of determination indicating the likelihood of an approximate line obtained using a least-squares method for the position of each of the plurality of detected marks. Letting y={y₁, y₂, . . . , y_{N}} be N sample values and f={f₁, f₂, . . . , f_{N}} be an estimated value using a linear regression expression by the least-squares method, the coefficient of determination can be obtained by

$${R}^{2} ≡ 1 - \frac{{\sum }_{i = 1}^{N} {( {y}_{i} - {f}_{i} )}^{2}}{{\sum }_{j = 1}^{N} {( {y}_{j} - \overline{y} )}^{2}} \qquad ( 1 )$$

The coefficient of determination obtained by this expression is a real number of 1 or less. The closer the coefficient of determination is to 1, the closer the distribution of sample values is to the line of the regression expression.

In step S1033, the controller CN determines the type of a model formula representing a deformation component in the predetermined region of the substrate based on the coefficient of determination that is the calculated evaluation value (third step). It can be judged, based on the coefficient of determination, whether the arrangement of the marks on the entire substrate or the arrangement of the marks in one shot region is linear. For example, the controller CN compares the calculated coefficient of determination with a threshold. For example, if the calculated coefficient of determination exceeds the threshold (for example, 0.9), it can be judged that the plurality of marks obtained by measurement are linearly arranged. If the calculated coefficient of determination does not exceed the threshold, it can be judged that the plurality of marks obtained by measurement are not linearly arranged. Note that the threshold can be set/changed to an arbitrary value. Hence, in this embodiment, model formulas of different types (correction methods) are determined in a case where the coefficient of determination does not exceed the threshold and in a case where the coefficient of determination does. For example, based on the judgement result, the controller CN selects an appropriate one of a plurality of model formulas (a plurality of correction methods) of different types stored in the storage unit SU (step S1033).

If the coefficient of determination does not exceed the threshold, the controller CN determines a first polynomial function as the model formula. On the other hand, if the coefficient of determination exceeds the threshold, the controller CN determines a second polynomial function whose number of terms is smaller than in the first polynomial function as the model formula. For example, if the marks are not linearly distributed, a correction value (represented by “ShiftX, ShiftY”) for the 1st-order linear component of translation, magnification, and rotation for the entire substrate or one shot region is represented by, for example, the following first polynomial functions using six types of coefficients.

$$ShiftX = {k}_{1} + {k}_{3} x + {k}_{5} y \\ ShiftY = {k}_{2} + {k}_{4} y + {k}_{6} x \qquad ( 2 )$$

On the other hand, if the marks are linearly distributed, the correction value (represented by “ShiftX, ShiftY”) for the 1st-order linear component of translation, magnification, and rotation for the entire substrate or one shot region is represented by, for example, the following second polynomial functions using four types of coefficients. At this time, as for the correction coefficients concerning the magnification and rotation, values common to ShiftX and ShiftY are used.

$$ShiftX = {k}_{1} + {k}_{3} x + {k}_{5} y \\ ShiftY = {k}_{2} + {k}_{3} y - {k}_{5} x \qquad ( 3 )$$

In a case where the measurement data are linearly distributed, if the correction coefficients are calculated using equations (2), the data of a component orthogonal to the distribution of the measurement data has no spread. For this reason, it may be impossible to correctly express the target shot region by the coefficients concerning the magnification or rotation and appropriately correct the components. In this case, the influence of the error can be suppressed by decreasing the number of correction coefficients and calculating the correction coefficients based on the components without unevenness in the distribution of data.

Note that in the above-described example, as the method of correcting the linear component of translation, magnification, and rotation, an example using a linear polynomial expression has been described. An arbitrary polynomial expression that corrects a higher-order deformation component other than this may be used, or a model other than the polynomial expression may be used.

After that, in step S1034, the shape of the predetermined region is specified using the model formula of the determined type (fourth step). Thus, the correction value is calculated such that the positional deviation of the pattern region is minimized based on the selected correction method.

According to the above-described embodiment, since the correction method is selected in accordance with the distribution state of alignment marks, and the shape of the whole substrate or one shot region is specified, lowering of the alignment accuracy can be suppressed.

FIG. 9 is a flowchart of a measuring method including processing of presenting the correction method determined using the position information of marks saved in the exposure apparatus in advance.

In step S201, the position information of each mark that is a measurement target is set. The set position information is stored in the storage unit SU. In step S202, using the position information of the marks stored in the storage unit SU, the controller CN calculates a coefficient of determination used to judge whether the distribution of the marks is linear. In step S203, the controller CN selects a correction method based on the calculated coefficient of determination. In step S204, the controller CN causes the display unit D to display information about the selected (determined) correction method (model formula type). In an example, the information about the correction method displayed on the display unit D can be a polynomial expression representing a correction value. On the display unit D, the coefficients of the polynomial expression and a change of the shape (shift, magnification, and rotation) corrected by the selected correction method may be displayed as a graph. Also, as the position information of the marks used to calculate the coefficient of determination, not only the position information stored in the storage unit SU but also the position information of the marks acquired by directly measuring the substrate by an external measuring apparatus may be used.

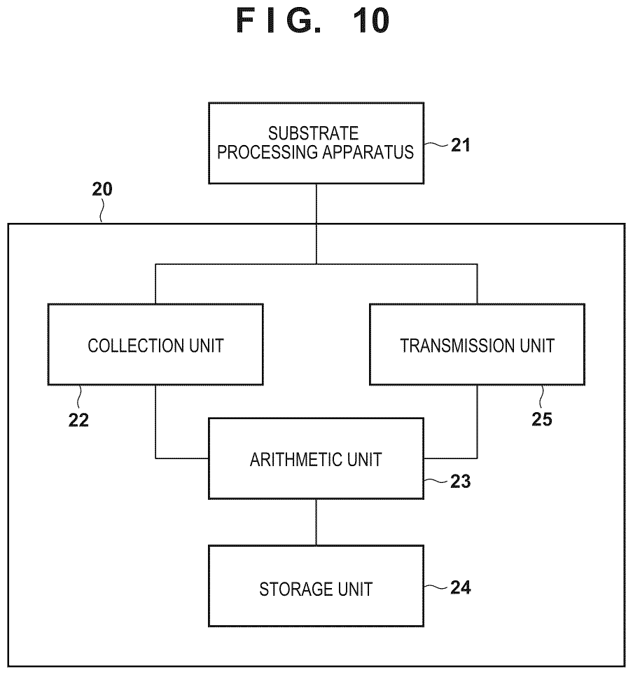

FIG. 10 shows an example of the configuration of an information processing system 20 according to the embodiment.

The information processing system 20 is connected to a substrate processing apparatus 21 via a network or a serial cable. The substrate processing apparatus 21 can be, for example, an exposure apparatus that transfers a circuit pattern to a substrate or a measuring apparatus that measures a pattern formed on a substrate. Also, the substrate processing apparatus need not be a single apparatus, and a plurality of processing apparatuses of different types may be connected.

Information such as the measurement data or design data of the substrate acquired by the substrate processing apparatus 21 is collected by a collection unit 22. An arithmetic unit 23 calculates a correction value for alignment using a correction method selected from among correction methods stored in a storage unit 24 based on the collected information and an alignment mark evaluation method described in the above embodiment. The correction value calculated by the arithmetic unit 23 is transmitted, by a transmission unit 25, to the connected substrate processing apparatus 21, and the substrate processing apparatus 21 executes substrate processing based on the transmitted correction value.

A lithography method for transferring a pattern to a substrate can be implemented using a lithography apparatus according to the above-described embodiment. The lithography method can include a step of specifying the shape of a predetermined region of a substrate in accordance with the above-described measuring method, and a step of obtaining the array of a plurality of regions of the substrate based on the specified shape. The lithography method can further include a step of transferring the pattern to a target position of the substrate while positioning the substrate based on the obtained array.

In the above-described embodiment, an exposure apparatus has been described as an example of the lithography apparatus. However, the present invention is not limited to this. The lithography apparatus may be an imprint apparatus that forms a pattern of an imprint material on a substrate using a mold (a die or a template) with an uneven pattern. Alternatively, the lithography apparatus may be a planarization apparatus that performs molding to planarize a composition on a substrate using a mold (planar template) including a planar portion without an uneven pattern. Also, the lithography apparatus may be an apparatus such as a drawing apparatus that performs drawing on a substrate using a charged particle ray (an electron ray or an ion beam) via a charged particle optical system, thereby forming a pattern on the substrate. Also, the lithography apparatus may be a measuring apparatus that measures a pattern formed on a substrate, thereby measuring a deviation amount with respect to the designed pattern.

### <Embodiment of Article Manufacturing Method>

The article manufacturing method according to the embodiment of the present invention is suitable for manufacturing an article, for example, a microdevice such as a semiconductor device or an element having a fine structure. The article manufacturing method according to this embodiment includes a step of transferring a pattern of an original to a substrate using the above-described lithography apparatus (an exposure apparatus, an imprint apparatus, a drawing apparatus, or the like), and a step of processing the substrate to which the pattern is transferred in the step. The manufacturing method also includes other known steps (oxidation, deposition, vapor deposition, doping, planarization, etching, resist removal, dicing, bonding, packaging, and the like). The article manufacturing method according to this embodiment is advantageous in at least one of the performance, quality, productivity, and production cost of the article, as compared to conventional methods.

The present invention is not limited to the above embodiments and various changes and modifications can be made within the spirit and scope of the present invention. Therefore, to apprise the public of the scope of the present invention, the following claims are made.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-080920, filed May 16, 2023, which is hereby incorporated by reference herein in its entirety.

What is claimed is:

1. A measuring method comprising:
detecting a plurality of marks including at least three marks existing on a substrate using a scope configured to capture images of the marks;
calculating an evaluation value indicating a distribution state of positions of the plurality of detected marks;
determining a type of a model formula representing a deformation component in a predetermined region of the substrate based on the calculated evaluation value; and
specifying a shape of the predetermined region using the model formula of the determined type.

2. The method according to claim 1, wherein the evaluation value is a coefficient indicating a likelihood of an approximate line obtained using a least-squares method for the position of each of the plurality of detected marks.

3. The method according to claim 2, wherein in the determining the type of the model formula, model formulas of different types are determined in a case where the coefficient does not exceed a threshold and in a case where the coefficient does.

4. The method according to claim 3, wherein if the coefficient does not exceed the threshold, a first polynomial function is determined as the model formula, and if the coefficient exceeds the threshold, a second polynomial function whose number of terms is smaller than in the first polynomial function is determined as the model formula.

5. The method according to claim 4, wherein each of the first polynomial function and the second polynomial function is a polynomial function representing deformation concerning a 1st-order linear component of translation, magnification, and rotation for the predetermined region.

6. A lithography method comprising:
specifying a shape of a predetermined region of a substrate in accordance with a measuring method according to claim 1;
obtaining an array of a plurality of regions of the substrate based on the specified shape; and
transferring a pattern to a target position of the substrate while positioning the substrate based on the obtained array.

7. The method according to claim 6, wherein
the predetermined region is a whole region of the substrate, and
a plurality of marks are located in a plurality of sample shot regions of the substrate, respectively.

8. The method according to claim 6, wherein
the predetermined region is one shot region of the substrate, and
a plurality of marks are located in the one shot region.

9. An article manufacturing method comprising:
transferring a pattern onto a substrate by a lithography method according to claim 6; and
processing the substrate that has undergone the transferring,
wherein an article is obtained from the substrate that has undergone the processing.

10. A computer-readable storage medium storing a program configured to cause a computer to execute a measuring method, the program comprising a program code configured to cause the computer to execute:
detecting a plurality of marks including at least three marks existing on a substrate using a scope configured to capture images of the marks;
calculating an evaluation value indicating a distribution state of positions of the plurality of detected marks;
determining a type of a model formula representing a deformation component in a predetermined region of the substrate based on the calculated evaluation value; and
specifying a shape of the predetermined region using the model formula of the determined type.

11. A lithography apparatus comprising:
a scope configured to capture an image of a mark provided on a substrate; and
a processor configured to calculate an evaluation value indicating a distribution state of positions of a plurality of marks including at least three marks detected using the scope, determines a type of a model formula representing a deformation component in a predetermined region of the substrate based on the calculated evaluation value, and specifies a shape of the predetermined region using the model formula of the determined type,
wherein a pattern is transferred to a target position of the substrate while positioning the substrate based on the specified shape.

12. The apparatus according to claim 11, wherein
the predetermined region is a whole region of the substrate, and
a plurality of marks are located in a plurality of sample shot regions of the substrate, respectively.

13. The apparatus according to claim 11, wherein
the predetermined region is one shot region of the substrate, and
a plurality of marks are located in the one shot region.

14. The apparatus according to claim 11, further comprising a controller configured to cause a display unit to display information about the determined model formula.
